(19) United States
(12) Patent Application Publication
(10) Pub. No.: US 2026/0111238 A1
(43) Pub. Date: Apr. 23, 2026

(54) MEMORY SLOT CONTROL METHOD AND APPARATUS, ELECTRONIC DEVICE, AND STORAGE MEDIUM

(71) Applicant: Suzhou MetaBrain Intelligent Technology, Suzhou, Jiangsu (CN)

(72) Inventors: Xiuqiang SUN, Suzhou, Jiangsu (CN); Shian Cheng, Suzhou, Jiangsu (CN); Baojun Liu, Suzhou, Jiangsu (CN); Binghui Zhang, Suzhou, Jiangsu (CN)

(21) Appl. No.: 19/168,015

(22) PCT Filed: May 31, 2024
(86) PCT No.: PCT/CN2024/096755

§ 371 Date: Sep. 23, 2025

(30) Foreign Application Priority Data
Dec. 20, 2023 (CN) 202311756575.1

(51) Int. Cl. G06F 3/06

(52) U.S. Cl. CPC G06F 3/0644; G06F 3/0604; G06F 3/0673

(57) ABSTRACT

Provided are a memory slot control method and apparatus, an electronic device, and a storage medium, which relate to the technical field of data processing. The method includes: in response to the startup of a server, acquiring, by a basic input output system, a set number of memory slots of a processor, in response to the set member of the memory slots failing in reaching a total capacity of memory slots, determining a target memory slot on the basis of a ratio of the set number of memory slots to the total capacity of memory slots, and controlling the target memory slot to be disabled and isolated, so as to achieve normal startup of the server.

### CROSS-REFERENCE TO RELATED APPLICATION

This application claims priority to Chinese Patent Application No. 202311756575.1, filed on Dec. 20, 2023 in China National Intellectual Property Administration and entitled “MEMORY SLOT CONTROL METHOD AND APPARATUS, ELECTRONIC DEVICE AND STORAGE MEDIUM”, which is hereby incorporated by reference in its entirety.

### FIELD

The present application relates to a memory slot control method and apparatus, an electronic device, and storage medium.

### BACKGROUND

The data and information of a computer mainly operate in memory. Even though some processors support a certain amount of cache, such cache merely serves the basic instruction execution requirements of the processor during startup and operation.

For example, a self-check program started during startup of a server and application programs running under a system all need to be supported by a certain number of memories, while servers of different frameworks vary with the insertion methods of memories. Usually, users buy products with maximum memories. However, users do not need to use too many memories in special situations and therefore unload unnecessary memories. Under such condition, memory slots need to be managed by removing hardware, which is troublesome and inconvenient.

### SUMMARY

According to embodiments of the present application, in a first aspect, a memory slot control method is provided, including:
in response to the startup of a server, acquiring, by a basic input output system, a set number of memory slots of a processor; and
controlling a target memory slot to be disabled and isolated so as to achieve normal startup of the server,
wherein the target memory slot is related to a ratio of the set number of memory slots to a total capacity of memory slots.

In a second aspect, a memory slot control apparatus is further provided, including:
an acquisition module, configured to, in response to the startup of a server, acquire a set number of memory slots of a processor through a basic input output system;
a determination module, configured to, in response to the set number of memory slots failing in reaching a total capacity of memory slots, determine a target memory slot based on a ratio of the set number of memory slots to the total capacity of memory slots; and
a control module, configured to control the target memory slot to be disabled and isolated so as to achieve normal startup of the server.

In a third aspect, the present application also provides an electronic device, including a memory, a processor, and a computer-readable instruction stored in the memory and executable by the processor, wherein the processor executes the computer-readable instruction to implement any of the memory slot control methods as described in the first aspect.

In a fourth aspect, the present application further provides a non-transitory computer-readable storage medium having a computer-readable instruction stored thereon, wherein the computer-readable instruction, when executed by the processor, implements any of the memory slot control methods as described in the first aspect.

In a fifth aspect, the present application further provides a computer-readable instruction product, including a computer-readable instruction, wherein the computer-readable instruction, when executed by the processor, implements any of the memory slot control methods as described in the first aspect.

The details of one or more embodiments of the present application are set forth in the accompanying drawings and the description below. Other features and advantages of the present application will become apparent from the specification, the drawings, and the claims.

### BRIEF DESCRIPTION OF THE DRAWINGS

In order to describe the technical solutions in the embodiments of the application more clearly, the drawings required to be used in the embodiments will be simply introduced below. It is apparent that the drawings described below are only some embodiments of the application. Other drawings may further be obtained by those skilled in the art according to these drawings without creative work.

FIG. 1 is a memory slot control method according to one or more embodiments of the present application;

FIG. 2 is a schematic diagram of memory disabling and isolating flows according to one or more embodiments of the present application;

FIG. 3 is a schematic diagram of a slot connection method according to one or more embodiments of the present application;

FIG. 4 is a schematic diagram of physical connection of memories according to one or more embodiments of the present application;

FIG. 5 is a flowchart of memory slot setting according to one or more embodiments of the present application;

FIG. 6 is a first flowchart of memory slot startup setting according to one or more embodiments of the present application;

FIG. 7 is a second flowchart of memory slot startup setting according to one or more embodiments of the present application;

FIG. 8 is a schematic structural diagram of a memory slot control apparatus according to one or more embodiments of the present application;

FIG. 9 is a schematic structural diagram of an electronic device according to one or more embodiments of the present application; and

FIG. 10 is a schematic structural diagram of a non-transitory computer-readable storage medium according to one or more embodiments of the present application.

### DETAILED DESCRIPTION

In order to make objectives, technical solutions, and advantages of the embodiments of the present application clearer, the technical solutions in the embodiments of the present application will be described clearly and completely below with reference to the accompanying drawings. Apparently, the described embodiments are only part of the embodiments of the present application, rather than all of them. All other embodiments obtained by those of ordinary skill in the art on the basis of the embodiments in the present application without creative work shall fall within the scope of protection of the present application.

In embodiments of the present application, servers of different frameworks impose different requirements on memory insertion. For example, the installation of one, two, four, eight, sixteen or more memories varies with requirements. Meanwhile, a central processing unit (CPU) supports one memory channel configured with two memories, whereby a number of corresponding memory slots is double a number of memory channels.

If a CPU, which supports 8 memory channels, indirectly supports the installation of 16 memory modules, two CPUs might support installation of 16 memory channels with 32 memory modules. In this way, a dual-processor server might be configured with maximum 32 memory modules which correspond to 32 memory slots. Usually, buyers buy products with the maximum memories, but actually do not need to use so many memory modules under particular conditions, so memory modules which are not required to be used need to be disabled.

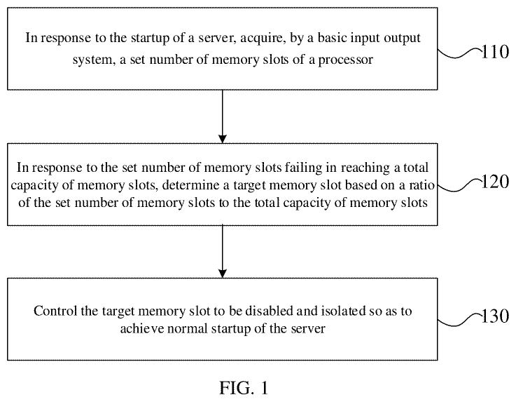

FIG. 1 is a memory slot control method provided in the embodiments of the present application, including:

Step 110: In response to the startup of a server, acquiring, by a basic input output system, a set number of memory slots of a processor.

In the embodiment of the present application, the server is fully configured by default when leaving a factory, which means that all memory slots in the server are completely inserted with memories. A user might further set a number of the memory slots of the processor when performing configuration reduction management on an actual memory number.

In one or more embodiments, one or more options might be added to a basic input output system (BIOS) interface to set the disabling and isolation of memory channels and the memory slots. In this way, a certain proportion of memory channels and memory slots might be chosen to be disabled and isolated according to a preset number, so as to meet the use requirements of closing and isolation the memories based on presetting.

In one or more embodiments, an option value might be set to multiple values such as “all”, “one-half,” “one-quarter”, “one-eighth”, “one-sixteenth”, and “one-thirty-second”. When a value is chosen, a BIOS disables a corresponding number of memory channels and memory slots according to the set value of a total capacity of memories to meet the use requirements on disabling and isolating memories according to presetting.

Step 120: In response to the set number of memory slots failing in reaching a total capacity of memory slots, determining a target memory slot based on a ratio of the set number of memory slots to the total capacity of memory slots.

Step 130: Controlling the target memory slot to be disabled and isolated so as to achieve normal startup of a server.

In the embodiments of the present application, when the set number of memory slots fails in reaching the total capacity of memory slots, it indicates that some memory slots need to be disabled and isolated, so as to further control the target memory slot to be disabled and isolated.

In one or more embodiments of the present application, determining the memory slot to be disabled and isolated needs to meet a certain rule, or failure to start up the server is resulted therefrom.

In the embodiments of the present application, each of the memory channels corresponds to two memory slots, namely a first memory slot (DIMM0 (Dual-Inline-Memory-Modules) and a second memory slot DIMM1; the rule of disabling the memory slot is to preferentially disable the memory on DIMM1 of the memory channel, and then to disable the memory on the DIMM0 of the memory channel.

In the embodiments of the present application, each of the channel slots is determined to comply with the rule according to a ratio of the set number of memory slots to the total capacity of memory slots. The memory slots that comply with the rule are retained for startup, whereas target memory slots that do not comply with the rule or position information are disabled and isolated to ensure normal startup of the server.

In the embodiments of the present application, whether the target memory slot which does not comply with the rule needs to be disabled and isolated might be determined according to the set number of memory slots set by the user and the total capacity of memory slots. Memory slots that comply with the rule in terms of number and slot information and are not target memory slots are retained for startup, whereas memory slots that do not comply with the rule or location information are disabled and isolated to ensure normal startup of the server. This solution does not rely on complex hardware operations and, while ensuring safe, reliable, and stable server operation, conveniently meets diverse user requirements for memory slot configuration. Moreover, disabling and isolating the target memory slot effectively avoids ineffective use of the memories, reduces operation cost and running power consumption of the server, and effectively prolongs the service life of the memories.

In some embodiments, the controlling the target memory slot to be disabled and isolated so as to achieve normal startup of a server includes:
an insertion status of each of memory slots is acquired based on data of each of memory slots;
memory slots that are in an inserted state and are not target memory slots are retained; or
memory slots that are in an inserted state and are target memory slots are disabled.

In one or more embodiments, if all memory slots are completely inserted with memories by default when leaving a factory, each of the corresponding memory slots is in the inserted state.

In another one or more optional embodiments, if some memory slots are not inserted with the memory, the insertion status of each of the memory slots needs to be further acquired according to the data of each of the memory slots.

In one or more embodiments, the insertion status of each of the memory slots is acquired via the BIOS of a mainboard or relevant system management software, so as determine the memory slots in the inserted state.

In the embodiments of the present application, whether the memory slot is the target memory slot is determined when retaining the memory slot. If it is determined that the memory slot is not the target memory slot, the memory slot is retained and ensured to function normally.

If the memory slot is the target memory slot, the memory slot is disabled to fulfill the purpose of isolation. Disabling the memory slot may be implemented via the BIOS of the mainboard or relevant system management software. Specific implementation methods may vary with mainboard models and software versions.

In one or more optional embodiments, after the step of acquiring the insertion status of each of the memory slots according to the data of each of the memory slots, the method further includes:
when the memory slot is in a non-inserted state, other memory slots are continuously traversed, and the server is started up after all memory slots are traversed.

In the embodiments of the present application, the insertion status of each of the memory slots is checked in turn from the first memory slot by traversing all the memory slots.

The insertion status of each of the memory slots is checked. If the memory slot is in the non-inserted state (namely an empty memory slot), the next memory slot is traversed continuously; and if the memory slot is in an inserted state (which means that the memory slot is inserted with a memory module), the next operation is implemented.

In the embodiments of the present application, when the memory slot is in the inserted state, the next memory slot is continuously traversed until all the memory slots are traversed. After all the memory slots are traversed, the server is started up according to memories retained in the memory slots.

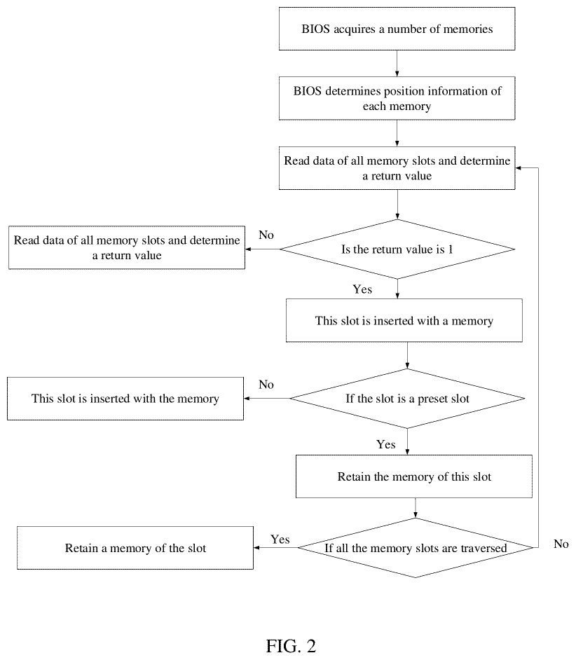

In one or more embodiments, FIG. 2 is a schematic diagram of memory disabling and isolating flows according to embodiments of the present application. As shown in FIG. 2, the following procedures are included.
First, a BIOS acquires a number of memories and then determines position information of each of the memories;
second, the BIOS reads data of all memory slots, and determines a return value of each of the memory slots;
when the return value is not 1, it indicates that the memory slot is inserted with no memory;
when the return value is 1, it indicates that the memory slot is inserted with a memory; and whether the memory slot is a target memory slot is further determined;
when the memory slot is the target memory slot, the memory slot is disabled; and when the memory slot is not the target memory slot, the memory slot is retained; and
after all memory slots are traversed, a server is started up.

In the embodiments of the present application, full consideration might be given to an insertion status of each of the memory slots to perform accurate control over the memory slots, so as to effectively ensure normal startup of a server.

In some embodiments, a method for acquiring the target memory slot includes:
when a set number of memory slots is half of a total capacity of memory slots, a second memory slot of a memory channel is set as the target memory slot.

In the embodiments of the present application, since the memory is inserted by fixed requirements, when half of the memory slots need to be disabled, DIMM1 of each of memory channels must be disabled while DIMM0 must remain enabled to ensure normal operation of a server.

Since each of the memory channels includes a first memory slot DIMM0 and a second memory slot DIMM1, second memory slots DIMM1 of all memory channels might be set as the target memory slots, and disabled and isolated.

In some embodiments, the controlling a target memory slot to be disabled and isolated so as to achieve normal startup of a server includes:
in a dual-processor system, when the total capacity of memory slots is 32 and the set number of slots is 16, all second memory slots of the memory channels in first and second processors are disabled and isolated to ensure normal startup of the server.

In one or more embodiments, the dual-processor system as described in the embodiments of the present application may be a configuration equipped with two physical processors, including a first processor and a second processor.

In the embodiments of the present application, when the total capacity of memory slots is 32 and the set number of memory slots is 16, it indicates that 16 memory slots need to be disabled and isolated, while the first memory slots DIMM0 need to be retained as much as possible, whereby the second memory slots DIMM1 of all memory channels in the first processor and the second processor might be disabled and isolated.

In some embodiments, a method for acquiring the target memory slots includes:
when a set number of memory slots is ¼ of a total capacity of memory slots, second memory slots of memory channels and half of the first memory slots of the memory channels are set as the target memory slots.

In the embodiments of the present application, when the set number of memory slots is ¼ of the total capacity of memory slots, the second memory slots DIMM1 of all memory channels are completely set as the target memory slots and disabled.

In this case, half of the first memory slots of all memory channels need to be set as the target memory slots, and disabled and isolated, and only ¼ of the total capacity of memory slots need to be retained at last.

In one or more embodiments, when the total capacity of memory slots of a dual-processor system is 32 and the set number of memory slots is 8, the second memory slots of all memory channels in a first processor and a second processor are disabled and isolated first, then the first memory slots of the latter four memory channels in the first processor and the second processor are disabled and isolated.

In the embodiments of the present application, when the set number of memory slots is 8, it indicates that only 8 memory slots need to be retained to run, and the other 24 target memory slots need to be disabled.

In the embodiments of the present application, to determine the target memory slots which need to be disabled and isolated, the 16 second memory slots of all memory channels in the first processor and the second processor are preferentially set as the target memory slots, and disabled and isolated.

Then, the first memory slots DIMM0 of the latter four memory channels in the first processor and the second processor might be disabled and isolated.

In the embodiments of the present application, the latter four memory channels might be latter four memory channels sequenced in a read sequence.

In the embodiments of the present application, each of the latter four memory channels includes a first memory slot DIMM0, whereby four target memory slots of the four memory channels in each of the processors might be further disabled and isolated, and 8 memory slots are retained at last.

In one or more embodiments, a method for acquiring target memory slots includes:
when a set number of memory slots is ⅛ of a total capacity of memory slots, second memory slots of all memory channels and ¾ of first memory slots of all memory channels are set as the target memory slots.

In the embodiments of the present application, when the set number of memory slots is ⅛ of the total capacity of memory slots, the second memory slots DIMM1 of all memory channels are first completely set as the target memory slots, and disabled and isolated.

Then, after the second memory slots DIMM1 of all memory channels in a first processor and a second processor are disabled and isolated, the first memory slots DIMM0 of the latter four memory channels in the first processor and the second processor are set as the target memory slots, and disabled and isolated.

Furthermore, the first memory slots DIMM0 of two memory channels, except the aforementioned four memory channels, in the first processor and the second processor might be set as the target memory slots, and disabled and isolated. Finally, only four memory slots are retained to run.

In some embodiments, when the total capacity of memory slots of a dual-processor system is 32, the set number of memory slots is 4, and the four set memory slots are not the first memory slots of the first memory channels and the second memory channels in the first processor and the second processor, the second memory slots of all memory channels in the first processor and the second processor are disabled and isolated, and then the first memory slots of the latter six memory channels in the first processor and the second processor disabled and isolated.

In the embodiments of the present application, when the set number of memory slots is 4, it indicates that only 4 memory slots need to be retained to run, and the other 28 target memory slots need to be disabled.

In the embodiments of the present application, after the set number of memory slots is determined, if it is currently detected that more than four memory slots are inserted with the memory, it indicates that some of the memory slots need to be disabled and isolated.

In another one or more embodiments, if it is currently detected that only four memory slots are inserted with the memory, an insertion status of the first memory slots of first memory channels and second memory channels in the first processor and the second processor might be further read; and if four first memory slots inserted with the memory are not the first memory slots DIMM0 of the first memory channels and the second memory channels in the first processor and the second processor, it indicates that target memory slots which need to be disabled and isolated exist.

Therefore, when the total capacity of memory slots of a dual-processor system is 32, the set number of memory slots is 4, and the four set memory slots are not the first memory slots of the first memory channels and the second memory channels in the first processor and the second processor, it indicates that target memory slots which need to be disabled and isolated exist.

In the embodiments of the present application, to determine the target memory slots which need to be disabled and isolated, the 16 second memory slots of all memory channels in the first processor and the second processor are preferentially set as the target memory slots, and disabled and isolated.

Then, the first memory slots DIMM0 of latter six memory channels in the first processor and the second processor might be disabled and isolated.

In the embodiments of the present application, the latter six memory channels might be latter six memory channels sequenced in a read sequence.

In the embodiments of the present application, each of the latter six memory channels includes a first memory slot DIMM0, whereby the six first memory slots DIMM1 of the six memory channels of each of the processors, namely 12 first memory slots DIMM1 in the-dual-processor system, might be further disabled and isolated, and four memory slots are retained at last.

In some embodiments, the method further includes:
when the total capacity of memory slots of the dual-processor system is 32, the set number of memory slots is 4, and the four set memory slots are the first memory slots of the first memory channels and the second memory channels in the first processor and the second processor, the server is started up.

In the embodiments of the present application, if four memory slots are inserted with the memory after the set number of the memory slot is determined, the insertion status of the first memory slots of the first memory channels and the second memory channels in the first processor and the second processor might further be read; and if the four first memory slots inserted with the memory are the first memory slots DIMM0 of the first memory channels and the second memory channels in the first processor and the second processor are inserted with the memory, it indicates that all other memory slots are not inserted with the memory and do not need to be disabled and isolated, and the server might be directly started up.

In some embodiments, a method for acquiring the target memory slots includes:
when the set number of memory slots is 1/16 of the total capacity of memory slots, the first memory slots and the second memory slots of other memory channels, except the first memory slots in the first memory channels, in the first processor and the second processor are set as the target memory slots.

In the embodiments of the present application, when the set number of memory slots is 1/16 of the total capacity of memory slots, the second memory slots DIMM1 of all memory channels might be first set as the target memory slots, and disabled and isolated.

Then, after the second memory channels DIMM1 of all memory channels in the first processor and the second processor are disabled and isolated, all other memory slots, except the first memory channels DIMM0 of the first memory channels, in the first processor and the second processor are set as the target memory slots, and disabled and isolated.

To be specific, when the set number of memory slots is 1/16 of the total capacity of memory slots, only the first memory slots DIMM0 of the first memory channels in the first processor and the second processor are retained, while all other memory slots are disabled and isolated.

In some embodiments, the controlling a target memory slot to be disabled and isolated so as to achieve normal startup of a server includes:
when the total capacity of memory slots of the dual-processor system is 32, the set number of memory slots is 2, and the two set memory slots are not the first memory slots of the first memory channels in the first processor and the second processor, the first memory slots and the second memory slots of other memory channels, except the first memory slots of the first memory channels, in the first processor and the second processor are set as the target memory slots, and disabled and isolated, so as to achieve the normal startup of the server.

In the embodiments of the present application, when the set number of memory slots is 2, it indicates that only 2 memory slots need to be retained to run, and the other 30 target memory slots need to be disabled.

In the embodiments of the present application, after the set number of memory slots is determined, if it is currently detected that more than two memory slots are inserted with the memory, it indicates that some of the memory slots need to be disabled and isolated.

In another one or more embodiments, if it is currently detected that only two memory slots are inserted with the memory, an insertion status of the first memory slots of first memory channels in the first processor and the second processor might be further read; and if two first memory slots inserted with the memory are not the first memory slots DIMM0 of the first memory channels in the first processor and the second processer, it indicates that target memory slots which need to be disabled and isolated exist.

In the embodiments of the present application, to determine the target memory slot which needs to be disabled and isolated, 16 second memory slots DIMM1 of all memory channels in the first processor and in the second processor are preferentially set as the target memory slots, and disabled and isolated.

Then, the first memory slots DIMM0 of latter seven memory channels in the first processor and the second processor might be disabled and isolated.

In the embodiments of the present application, the latter seven memory channels might be latter seven memory channels sequenced in a read sequence.

In some embodiments, the method further includes:

When the total capacity of memory slots of a dual-processor system is 32, the set number of memory slots is 2, and the two set memory slots are the first memory slots of the first memory channels in the first processor and the second processor, the server is started up.

In the embodiments of the present application, if two memory slots are inserted with the memory after the set number of memory slots is determined, the insertion status of the first memory slots of the first memory channels in the first processor and the second processor might be further read; and if the two first memory slots DIMM0 inserted with the memory are the first memory slots of the first memory channels in the first processor and the second processor, it indicates that all other memory channels are not inserted with the memory and do not need to be disabled and isolated, and then the server might be directly started up.

In some embodiments, a method for acquiring the target memory slots includes:
when the set number of memory slots is 1/32 of the total capacity of memory slots, the first memory slots and the second memory slots of other memory channels, except the first memory slots of the first memory channel, in the first processor are set as the target memory slots.

In the embodiments of the present application, when the set number of memory slots is 1/32 of the total capacity of memory slots, the second memory slots DIMM1 of all memory channels are first set as the target memory slots, and disabled and isolated.

Then, after the second memory slots DIMM1 of all memory channels in the first processor and the second processor are closed and isolated, all memory slots in the second processor are disabled and isolated; next, all other memory slots, except the first memory slots DIMM0 of the first memory channels, in the first processor are set as the target memory slots, and disabled and isolated.

To be specific, when the set number of memory slots is 1/32 of the total capacity of memory slots, only the first memory slots DIMM0 of the first memory channel in the first processor are retained, while all other memory slots are disabled and isolated.

In some embodiments, the controlling a target memory slot to be disabled and isolated so as to achieve normal startup of a server includes:
when the total capacity of memory slots of the dual-processor system is 32, the set number of memory slots is 1, and the one set memory slots is not the first memory slot of the first memory channel in the first processor, the first memory slots and the second memory slots of other memory channels, except the first memory slots of the first memory channels, in the first processor are set as the target memory slots, and disabled and isolated, so as to achieve the normal startup of the server.

In the embodiments of the present application, when the set number of memory slots is 1, it indicates that only one memory slot needs to be retained to run, and the other 31 target memory slots need to be disabled.

In the embodiments of the present application, after the set number of memory slots is determined, if it is currently detected that more than one memory slot is inserted with the memory, it indicates that some of the memory slots need to be disabled and isolated.

In another one or more in some embodiments, if it is currently detected that only one memory slot is inserted with the memory, an insertion status of the first memory slots of first memory channels in the first processor might be further read; and if the one first memory slot inserted with the memory is not the first memory slots DIMM0 of the first memory channels in the first processor, it indicates that target memory slots which need to be disabled and isolated exist.

In the embodiments of the present application, to determine the target memory slot which needs to be disabled and isolated, 16 second memory slots DIMM1 of all memory channels in the first processor and in the second processor are preferentially set as the target memory slots, and disabled and isolated.

Then, the first memory slots DIMM0 of all memory channels in the second processor might be isolated and closed. The first memory slots DIMM0 of the latter seven memory channels in the first processor might be disabled and isolated, while only the first memory slot of the first memory channel in the first processor is retained.

In the embodiments of the present application, the latter seven memory channels might be latter seven memory channels sequenced in a read sequence.

In some embodiments, the method further includes:
when the total capacity of memory slots of a dual-processor system is 32, the set number of memory slots is 1, and the one set memory slot is the first memory slot of the first memory channel in the first processor, the server is started up.

In the embodiments of the present application, if only one memory slot is inserted with the memory after the set number of memory slots is determined, the insertion status of the first memory slots of the first memory channels in the first processor might be further read; and if the one first memory slot DIMM0 inserted with the memory is the first memory slot of the first memory channel in the first processor, it indicates that all other memory channels are not inserted with the memory and do not need to be disabled and isolated, and then the server might be directly started up.

In the embodiments of the present application, the number of memory slots is further set via BIOS options to implement control over the memory slots. During startup of the server, the BIOS calculates identified memories and statistically collects the specific slot information of each slot inserted with memories; if the number and the slot position information comply with a rule, the memories are retained and the server is started up; and if the number and the position information do not comply with the rule, the memories with incorrect position information are disabled and isolated to ensure the normal startup function of the server and the safe reliable operation of the server, to meet the practical service demand of users, prolong the service life of the memories and reduce operation cost. The embodiments of the present application not only achieve dynamic management on functional features such as the memory number and capacity of server without removing the memories from the server, but also prolongs the service life of the memories and the working efficiency of the operation stuff.

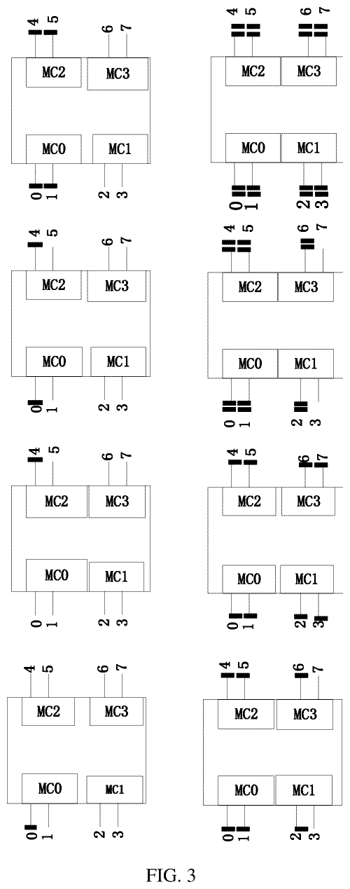

FIG. 3 is a schematic diagram of a slot connection method according to embodiments of the present application. As shown in FIG. 3, when only one memory slot is set, the memory slot might be set at a memory channel 0 or at a memory channel 4.

When only two memory slots are set, the two memory slots might be respectively set at the memory channel 0 and the memory channel 4; and when four memory slots are set, the four memory slots might be respectively set at the memory channel 0, a memory channel 1, the memory channel 4 and a memory channel 5.

When six memory slots are set, the memory slots might be respectively set at the memory channel 0, the memory channel 1, a memory channel 2, the memory channel 4, the memory channel 5, and a memory channel 6.

When eight memory slots are set, the memory slots might be respectively set at the memory channel 0, the memory channel 1, the memory channel 2, a memory channel 3, the memory channel 4, the memory channel 5, the memory channel, 6 and a memory channel 7.

When 12 memory slots are set, two memory slots might be set at each of the memory channel 0, the memory channel 1, the memory channel 2, the memory channel 4, the memory channel 5, and the memory channel 6.

When 12 memory slots are set, two memory slots might be set at each of the memory channel 0, the memory channel 1, the memory channel 2, the memory channel 3, the memory channel 4, the memory channel 5, the memory channel 6, and the memory slot 7.

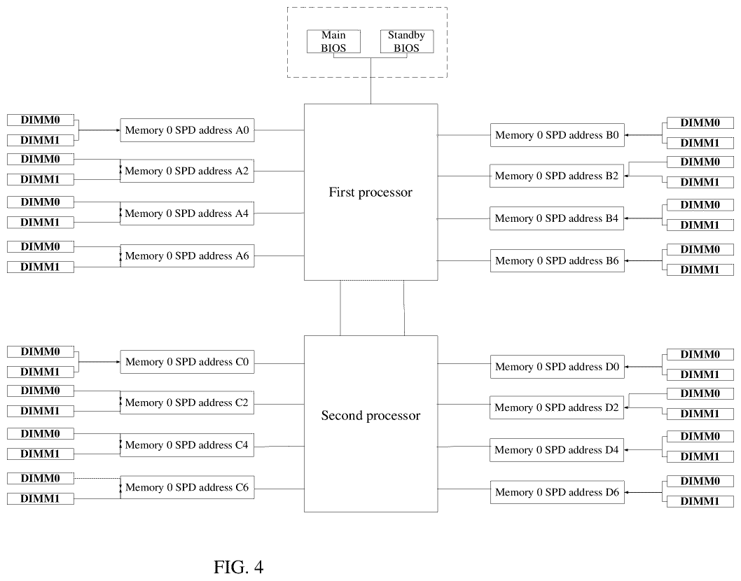

FIG. 4 is a schematic diagram of physical connection of memories according to embodiments of the present application. As shown in FIG. 4, a first processor and a second processor are included, each of the processors includes 8 memory channels, and each of the memory channels corresponds to two memory slots, namely DIMM1 and DIMM2. A main BIOS and a standby BIOS are connected to the first processor via bus protocols such as LPC/SPI/QSPI; the first processor is connected with the second processor; the main BIOS is configured to control the 16 memory slots corresponding to the first processor, and the standby BIOS is configured to control 16 memory slots corresponding to the second processor via the first processor.

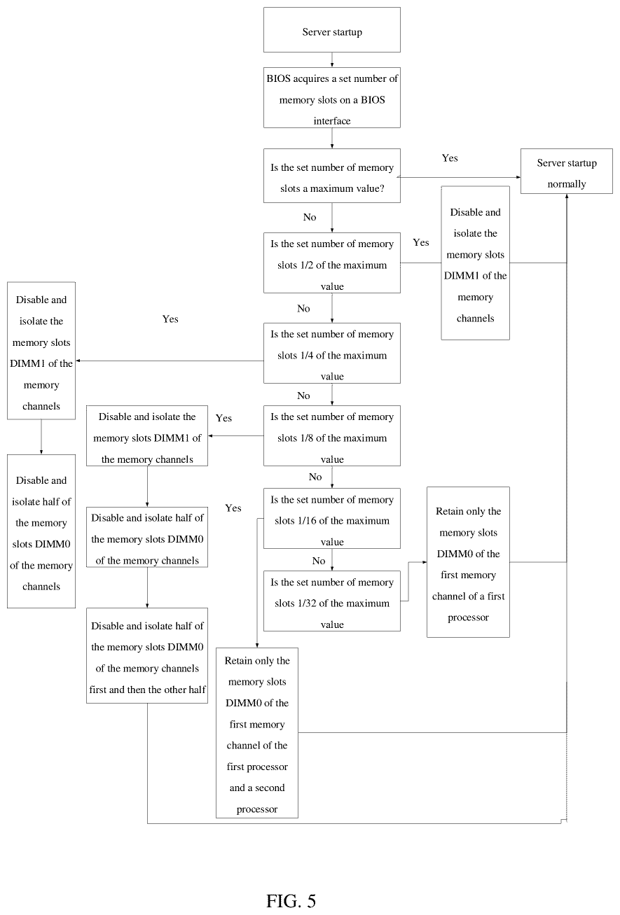

FIG. 5 is a flowchart of memory slot setting according to embodiments of the present application. As shown in FIG. 5, the following procedures are included: to start up a server, a BIOS acquires a set number of memory slots on a BIOS interface, and starts up the server when the set number of memory slots is consistent with a total capacity of memory slots.

When the set number of memory slots is half of the total capacity of memory slots, a second memory slot of a memory channel is set as a target memory slot.

When the set number of memory slots is ¼ of the total capacity of memory slots, the second memory slots of the memory channels and half of first memory slots of the memory channels are set as the target memory slots.

When the set number of memory slots is ⅛ of a total capacity of memory slots, second memory slots of all memory channels and ¾ of first memory slots of all memory channels are set as the target memory slots.

When the set number of memory slots is 1/16 of the total capacity of memory slots, the first memory slots and the second memory slots of other memory channels, except the first memory slots of the first memory channel, in the first processor are set as the target memory slots.

When the set number of memory slots is 1/32 of the total capacity of memory slots, the first memory slots and the second memory slots of other memory channels, except the first memory slots of the first memory channel, in the first processor are set as the target memory slots.

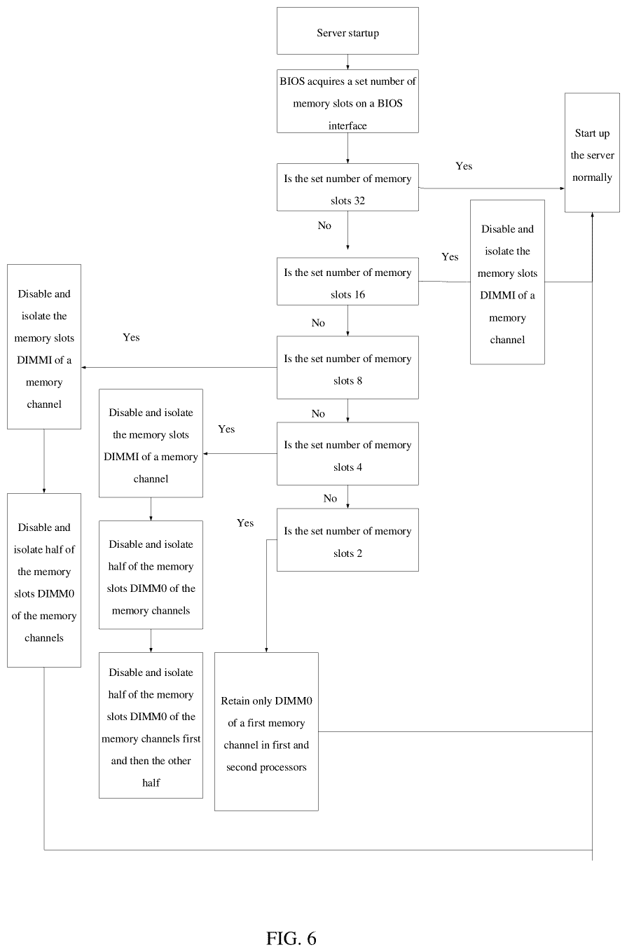

FIG. 6 is a first flowchart of memory slot startup setting according to embodiments of the present application; as shown in FIG. 6, the following procedures are included:
after the server is started up, a BIOS detects memory data and memory position information;
when a set number of memory slots is 2, and two set memory slots are not the first memory slots of first memory channels in a first processor and a second processor, first memory slots and second memory slots of other memory channels, except the first memory slots of the first memory channels, in the first processor and the second processor, are set as target memory slots, and disabled and isolated.

When the set number of memory slots is 2, and the two set memory slots are the first memory slots of the first memory channels in the first processor and the second processor, the server is started up.

When the set number of memory slots is 4 and the four set memory slots are not the first memory slots of the first memory channels and the second memory channels in the first processor and the second processor, the second memory slots of all memory channels in the first processor and the second processor are disabled and isolated, and then first memory channels of latter six memory channels in the first processor and the second processor are disabled and isolated.

When the set number of memory slots is 4 and the four set memory slots are the first memory slots of the first memory channels and the second memory channels in the first processor and the second processor, the server is started up.

When the set number of memory slots is 8, the second memory slots of all memory channels in the first processor and the second processor are disabled and isolated first, and then first memory channels of latter four memory channels in the first processor and the second processor are disabled and isolated.

When the set number of memory slots is 16, the second memory slots of all memory channels in the first processor and the second processor are disabled and isolated.

When the set number of memory slots is 32, whether the memory slots are all memory slots in the first processor and the second processor is determined, and if it is determined that the memory slots are all memory slots in the first processor and the second processor, the server is started up normally.

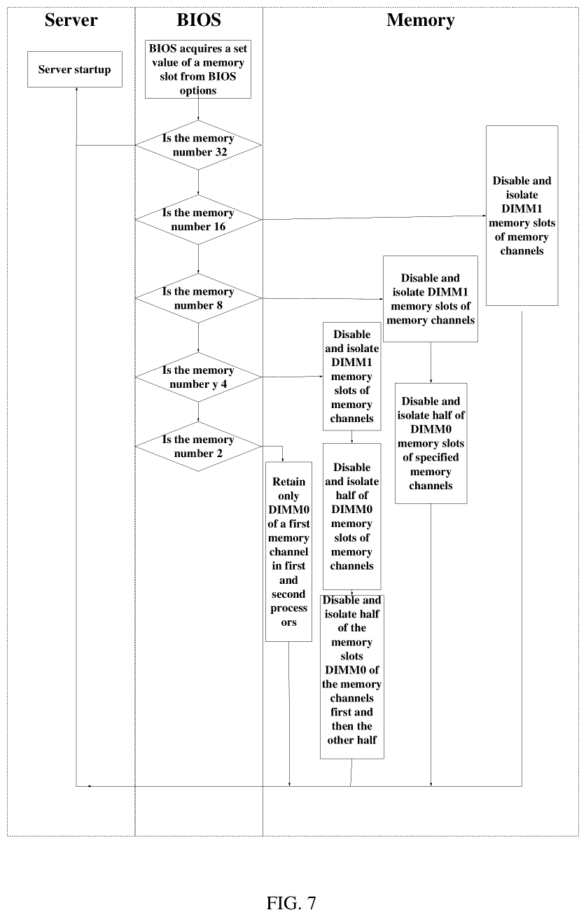

FIG. 7 is a second flowchart of memory slot startup setting according to embodiments of the present application. As shown in FIG. 7, the following procedures are included:

After a server is started up, a BIOS in the server further detects a memory number and memory slot position in the server.

When the number of the memory slots is 32, the BIOS determines whether all memory slots inserted with a memory are first memory slots and second memory slots of all memory channels in a first processor and a second processor; and if so, the server is started up normally.

When the number of the memory slots is 16, the BIOS determines whether all 16 memory slots inserted with the memory are the first memory slots in the first processor and the second processor, and if so, the server is started up normally.

If the 16 memory slots inserted with the memory are not the first memory slots in the first processor and the second processor, the second memory slots of all memory channels in the first processor and the second processor are disabled and isolated.

When the number of the memory slots is 8, the second memory slots of all memory channels in the first processor and the second processor are disabled and isolated first, and then the first memory slots of latter four memory channels in the first processor and the second processor are disabled and isolated.

When the number of the memory slots is 4 and the four set memory slots are the first memory slots of the first memory channels and the second memory channels in the first processor and the second processor, the server is started up.

When the four memory slots are not the first memory slots of the first memory channels and the second memory channels in the first processor and the second processor, the second memory slots of all memory channels in the first processor and the second processor are disabled and isolated first, and then the first memory slots of the latter six memory channels in the first processor and the second memory processor are disabled and isolated.

When the number of the memory slots is 2 and the two memory slots are the first memory slots of the first memory channels in the first processor and the second processor, the server is started up.

When the two memory slots are not the first memory slots of the first memory channels in the first processor and the second processor, the first memory slots and the second memory slots of other memory channels, except the first memory slots of the first memory channels, in the first processor and the second processor are set as the target memory slots, and disabled and isolated.

It shall be understood that, steps of the flowcharts in FIG. 1, FIG. 2 and FIG. 5 to FIG. 7 are shown in turn by arrows, but are not necessarily implemented by arrows. Unless otherwise clearly specified in the text, the steps are not implemented in strict sequences. The steps might be implemented in other sequences. Moreover, at least a part of the steps in FIG. 1, FIG. 2 and FIG. 5 to FIG. 7 include multiple sub-steps or multiple stages. The sub-steps or stages are not necessarily performed at the same time, but might be implemented at different time. The sub-steps or stages are not necessarily implemented in turn, but implemented in turn or alternatively with at least a part of other steps, or other sub-steps, or stages.

In the following, a memory slot control apparatus provided in the embodiments of the present application is described, and the memory slot control apparatus described below corresponds to the memory slot control method described above, and the two may be referred to each other.

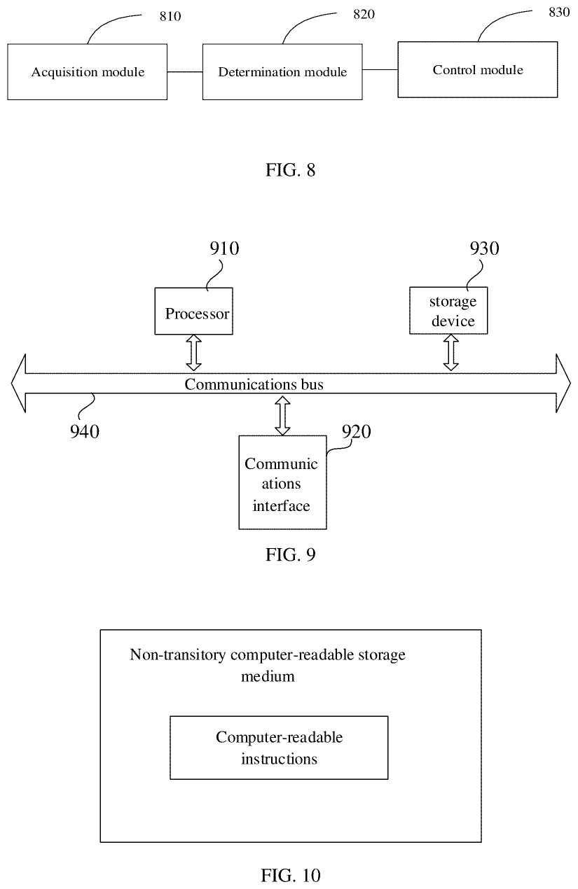

FIG. 8 is a schematic structural diagram of a memory slot control apparatus according to embodiments of the present application. As shown in FIG. 8, the memory slot control apparatus includes:
an acquisition module 810, configured to: in response to the startup of a server, acquire a set number of memory slots of a processor based on a basic input output system;
a determination module 820, configured to: when the set number of memory slots fails in reaching a total capacity of memory slots, determine a target memory slot on the basis of a ratio of the set number of memory slots to the total capacity of memory slots; and
a control module 830, configured to control the target memory slot to be disabled and isolated, so as to achieve normal startup of the server.

Specific definitions of the memory slot control apparatus might be referred to definitions of the above-described memory slot control method, and therefore are not repeatedly described. Each of the modules in the memory slot control apparatus might be completely or partly implemented through software, hardware or combinations thereof. Each of the modules might be built in in form of hardware or different from the processor of a computer device, or stored in memories of the computer device in form of software, whereby the processors revoke and implement operations corresponding to the above-mentioned modules.

FIG. 9 is a schematic diagram of an electronic device provided in the embodiments of the present application. As shown in FIG. 9, the electronic device may include: a processor 910, a communications interface 920, a storage device 930, and a communications bus 940, wherein the processor 910, the communications interface 920s and the storage device 930 communicate with one another via the communications bus 940. The processor 910 might revoke logic instructions in the storage device 930 to implement the memory slot control methods according to one or more embodiments above.

Furthermore, when realized in form of software functional unit and sold or used as an independent product, logic instructions in the storage device 930 might be stored in a computer-readable readable storage medium. Based on such an understanding, the technical solutions of the application substantially or parts making contributions to the conventional art or part of the technical solutions may be embodied in form of software product, and the computer software product is stored in a storage medium, including a plurality of instructions configured to enable a computer device (which may be a personal computer, a server, a network device or the like) to execute all or part of the steps of the method in each embodiment of the application. The above-mentioned storage medium includes: various media capable of storing program codes such as a U disk, a read-only memory (ROM), a random access memory (RAM), a magnetic disk or an optical disk.

In another aspect, the present application further provides a computer-readable instruction product, the computer-readable instruction product including computer-readable instructions, wherein the computer-readable instructions might be stored in a non-transitory computer-readable storage medium, and when the computer-readable instructions are implemented by the processor, a computer might implement the memory slot control method in one or more embodiments.

In another aspect, with reference to FIG. 10, the present application further provides a non-transitory computer-readable storage medium, having computer-readable instructions stored therein, and the computer-readable instructions implemented by the processor to implement the memory slot control method in one or more embodiments.

The embodiments of the device described above are merely illustrative. The units described as separate components may or may not be physically separated, and components shown as units may or may not be physical entities. They may be located in one place or distributed across multiple network units. Part or all of the modules may be selected to achieve the purpose of the solutions of the embodiments according to a practical requirement. A person of ordinary skill in the art would have been able to understand and implement without involving any inventive effort.

From the above descriptions about the implementation modes, those skilled in the art may clearly know that the implementation modes may be implemented in a manner of combining software and a necessary universal hardware platform, and of course, may also be implemented through hardware. Based on such an understanding, the technical solutions may be embodied in form of software products, and the computer software product is stored in a storage medium, such as a ROM/RAM, a disk, a CD-ROM, etc., including a plurality of instructions configured to enable a computer device (which may be a personal computer, a server, a network device or the like) to execute all or part of the method in each embodiment of the present application.

Finally, it should be noted that the above-mentioned embodiments are merely illustrative of the technical solution of the present application, and do not limit same; while the present application has been described in detail with reference to the foregoing embodiments, those skilled in the art will appreciate that: the technical solutions disclosed in the above-mentioned embodiments might still be modified or some of the technical characteristics might be replaced by equivalents; however, these modifications or substitutions do not depart from the spirit and scope of the technical solutions of the embodiments of the present application in nature.

1. A memory slot control method, comprising:
in response to a startup of a server, acquiring, by a basic input output system, a set number of memory slots of a processor;
in response to a set number of memory slots failing in reaching a total capacity of memory slots, determining target memory slots based on a ratio of the set number of memory slots to the total capacity of memory slots; and wherein the set number of memory slots comprises at least one of the following: ¼ of a total memory slot capacity, ⅛ of the total memory slot capacity, 1/16 of the total memory slot capacity, and 1/32 of the total memory slot capacity;
controlling the target memory slots to be disabled and isolated so as to achieve normal startup of the server; and wherein
the method for determining the target memory slots comprises:
in response to the set number of memory slots being ¼ of the total capacity of memory slots, setting second memory slots of memory channels and half of first memory slots of the memory channels as the target memory slots;
in response to the set number of memory slots being ⅛ of the total capacity of memory slots, setting the second memory slots of the memory channels and ¾ of the first memory slots of the memory channels as the target memory slots;
in response to the set number of memory slots being 1/16 of the total capacity of memory slots, setting first memory slots and second memory slots of other memory channels, except first memory slots of first memory channels, in a first processor and a second processor as the target memory slots; and
in response to the set number of memory slots being 1/32 of the total capacity of memory slots, setting first memory slots and second memory slots of other memory channels, except a first memory slot of a first memory channel, in the first processor as the target memory slots.

2. The memory slot control method according to claim 1, wherein the controlling the target memory slots to be disabled and isolated so as to achieve normal startup of the server comprises:
acquiring an insertion status of each memory slot based on data of each memory slot;
in response to the insertion status of the memory slot being an inserted state and the memory slot being a non-target memory slot, retaining the non-target memory slot; and-of
in response to the insertion status of the memory slot being the inserted state and the memory slot being a target memory slot, disabling the target memory slot.

3. The memory slot control method according to claim 2, wherein after the acquiring an insertion status of each memory slot based on data of each memory slot, the method further comprises:
in response to the memory slot being in a non-inserted state, continuously traversing other memory slots, and starting up the server after all memory slots are traversed.

4. The memory slot control method according to claim 1, wherein the a method for determining the target memory slot comprises:
in response to the set number of memory slots being half of the total capacity of memory slots, setting the second memory slots of the memory channels as the target memory slot.

5. The memory slot control method according to claim 4, wherein the controlling the target memory slots to be disabled and isolated so as to achieve normal startup of the server comprises:
in response to the total capacity of memory slots of a dual-processor system being 32 and the set number of memory slots being 16, disabling and isolating second memory slots of all-memory channels in the first processor and the second processor so as to achieve the normal startup of the server.

6. (canceled)

7. The memory slot control method according to claim 1, wherein the controlling the target memory slots to be disabled and isolated so as to achieve normal startup of the server comprises:
in response to the total capacity of memory slots of a dual-processor system being 32 and the set number of memory slots being 8, disabling and isolating second memory slots of all memory channels in the first processor and the second processor, and then disabling and isolating first memory slots of latter four memory channels in the first processor and the second processor so as to achieve the normal startup of the server.

8. (canceled)

9. The memory slot control method according to claim 1, wherein the controlling the target memory slots to be disabled and isolated so as to achieve normal startup of the server comprises:
in response to the total capacity of memory slots of a dual-processor system being 32, the set number of memory slots being 4, and the four set memory slots-are not being the first memory slots of the first memory channels and second memory channels in the first processor and the second processor, disabling and isolating second memory slots of all memory channels in the first processor and the second processor, and then disabling and isolating first memory slots of latter six memory channels in the first processor and the second processor, so as to achieve the normal startup of the server.

10. The memory slot control method according to claim 9, further comprising:
in response to the total capacity of memory slots of the dual-processor system being 32, the set number of memory slots being 4 and the four set memory slots being the first memory slots of the first memory channels and the second memory channels in the first processor and in the second processor, starting up the server.

11. (canceled)

12. The memory slot control method according to claim 1, wherein the controlling the target memory slots to be disabled and isolated so as to achieve normal startup of the server comprises:
in response to the total capacity of memory slots of a dual-processor system being 32, the set number of memory slots being 2, and the two set memory slots being not the first memory slots of the first memory channels in the first processor and the second processor, setting the first memory slots and the second memory slots of the other memory channels, except the first memory slots of the first memory channels, in the first processor and the second processor as the target memory slots, and disabling and isolating the target memory slots, so as to achieve the normal startup of the server.

13. The memory slot control method according to claim 12, further comprising:
in response to the total capacity of memory slots of the dual-processor system being 32, the set number of memory slots being 2, and the two set memory slots being the first memory slots of the first memory channels in the first processor and the second processor, starting up the server.

14. (canceled)

15. The memory slot control method according to claim 1, wherein the controlling the target memory slots to be disabled and isolated so as to achieve normal startup of the server comprises:
in response to the total capacity of memory slots of a dual-processor system being 32, the set number of memory slots being 1, and the one set memory slot being not the first memory slot of the first memory channel in the first processor, setting the first memory slots and the second memory slots of the other memory channels, except the first memory slot of the first memory channel, in the first processor as the target memory slots, and disabling and isolating the target memory slots, so as to achieve the normal startup of the server.

16. The memory slot control method according to claim 15, further comprising:
in response to the total capacity of memory slots of the dual-processor system being 32, the set number of memory slots being 1, and the one set memory slot being the first memory slot of the first memory channel in the first processor, starting up the server.

17. The memory slot control method according to claim 1, further comprising:
in response to the set number of memory slots being consistent with the total capacity of memory slots, starting up the server.

18. (canceled)

19. An electronic device, comprising a storage device, a processor, and a computer-readable instruction stored in the storage device and executable by the processor, wherein the processor, when executing the computer-readable instruction, implements a memory slot control method comprising:
in response to a startup of a server, acquiring, by a basic input output system, a set number of memory slots of the processor;
in response to a set number of memory slots failing in reaching a total capacity of memory slots, determining target memory slots based on a ratio of the set number of memory slots to the total capacity of memory slots; and wherein the set number of memory slots comprises at least one of the following: ¼ of a total memory slot capacity, ⅛ of the total memory slot capacity, 1/16 of the total memory slot capacity, and 1/32 of the total memory slot capacity;
controlling the target memory slots to be disabled and isolated so as to achieve normal startup of the server; and wherein
the method for determining the target memory slots comprises:
in response to the set number of memory slots being ¼ of the total capacity of memory slots, setting second memory slots of memory channels and half of first memory slots of the memory channels as the target memory slots;
in response to the set number of memory slots being ⅛ of the total capacity of memory slots, setting the second memory slots of the memory channels and ¾ of the first memory slots of the memory channels as the target memory slots;
in response to the set number of memory slots being 1/16 of the total capacity of memory slots, setting first memory slots and second memory slots of other memory channels, except first memory slots of first memory channels, in a first processor and a second processor as the target memory slots; and
in response to the set number of memory slots being 1/32 of the total capacity of memory slots, setting first memory slots and second memory slots of other memory channels, except a first memory slot of a first memory channel, in the first processor as the target memory slots.

20. A non-transitory computer-readable storage medium, having a computer-readable instruction stored thereon, and wherein the computer-readable instruction, when executed by a processor, implements a memory slot control method comprising:
in response to a startup of a server, acquiring, by a basic input output system, a set number of memory slots of the processor;
in response to a set number of memory slots failing in reaching a total capacity of memory slots, determining target memory slots based on a ratio of the set number of memory slots to the total capacity of memory slots; and wherein the set number of memory slots comprises at least one of the following: ¼ of a total memory slot capacity, ⅛ of the total memory slot capacity, 1/16 of the total memory slot capacity, and 1/32 of the total memory slot capacity;
controlling the target memory slots to be disabled and isolated so as to achieve normal startup of the server; and wherein
the method for determining the target memory slots comprises:
in response to the set number of memory slots being ¼ of the total capacity of memory slots, setting second memory slots of memory channels and half of first memory slots of the memory channels as the target memory slots;
in response to the set number of memory slots being ⅛ of the total capacity of memory slots, setting the second memory slots of the memory channels and ¾ of the first memory slots of the memory channels as the target memory slots;
in response to the set number of memory slots being 1/16 of the total capacity of memory slots, setting first memory slots and second memory slots of other memory channels, except first memory slots of first memory channels, in a first processor and a second processor as the target memory slots; and
in response to the set number of memory slots being 1/32 of the total capacity of memory slots, setting first memory slots and second memory slots of other memory channels, except a first memory slot of a first memory channel, in the first processor as the target memory slots.

21. The memory slot control method according to claim 1, wherein the method further comprising:
adding one or more options to a basic input output system (BIOS) interface to set the disabling and isolation of the memory channels and the memory slots.

22. The memory slot control method according to claim 2, wherein the acquiring an insertion status of each memory slot based on data of each memory slot comprises:
acquiring the insertion status by the basic input output system (BIOS) of a mainboard.

23. The memory slot control method according to claim 2, wherein a method of determining the insertion status of the memory slot comprises:
reading a return value of each of the memory slots by the basic input output system (BIOS); and
in response to the return value being not 1, determining the insertion status of the memory slot being an inserted state with no memory.

24. The memory slot control method according to claim 23, wherein the method further comprises:
in response to the return value being 1, determining the insertion status of the memory slot being an inserted state with a memory.

25. The memory slot control method according to claim 1, wherein each of the memory slots comprises at least one first memory slot and one second memory slot.
